(19) United States
(12) Patent Application Publication
(10) Pub. No.: US 2007/0099450 A1
(43) Pub. Date: May 3, 2007

(54) SIGNAL SWITCHING (DISTRIBUTING) BOX STRUCTURE

(76) Inventor: Chin-Chang Huang, Ban-Qiao City (TW)

Correspondence Address: Connolly Bove Lodge & Hutz LLP, P.O. Box 2207, Wilmington, DE, 19899-2207, US

(21) Appl. No.: 11/553,026

(22) Filed: Oct. 26, 2006

(30) Foreign Application Priority Data
Nov. 2, 2005 (CN) 094218900

(51) Int. Cl. H05K 1/00

(52) U.S. Cl. 439/76.1

(57) ABSTRACT

A signal switching (distributing) box structure comprises an upper housing and lower housing, the internal portion thereof is allowed to form a receiving space through the combination of the upper housing and the lower housing. At least one side of the lower housing is provided with at least one receiving hole for receiving a head of each adaptor and the rear end of the receiving hole is connected with a fixing sheet inside the lower housing. Positioning holes corresponding to the receiving holes are disposed on the fixing sheet to allow the heads of the adaptors to be locked through the disposition of the positioning holes, two side of the fixing sheet are respectively disposed with one fixing rod; the fixing sheet is allowed to fix on the lower housing through the disposition of the fixing rods. The heads of the adaptors are completely received in the receiving holes to enable them not to be exposed outside the outer rim of the housing when the head of the adaptor is locked on the fixing sheet. In the meantime, the heads of the adaptors are allowed to receive in the upper and the lower housings when they are combined with each other. Whereby, not only a collision can be avoided when the box is moved, but also electromagnetic wave interference can be avoided effectively when the box is used.

### BACKGROUND OF THE INVENTION

1. Field of the Invention

The present invention relates to a signal switching (distributing) box structure, and more particularly to a signal switching (distributing) box structure capable of reducing use space effectively and enhance the prevention of electromagnetic wave interference,

2. Description of Related Art

The situation that a several computer screens or printers are shared is gradually increased under the condition that the cost of a personal computer is gradually lowered down. The most popular use way is the installment of a switch box at the present under a financial consideration; the switch box here allows a user to switch to use different screens or printers, and a sharing purpose can be attained. No matter what it is a switch box used for the screens or the printers, the entire structure thereof is to connect and install heads of needed adaptors on the main body of the switch box, and then to allow them to connect with a device through a connection line to attain to the switching purpose. However, the head of the adaptor of the switch box is exposed out of the main body; it caused a user to occupy a larger use space when he uses the adaptors. In the meantime, because the head of the adaptor is exposed outside, it leads to the collision easily to cause the head of the adaptor to be damaged when it is moved to use. Besides, the head of the adaptor is exposed outside of the switch box such that the electromagnetic wave interference is caused to increase to embarrass the user while using the switching box; this is very inconvenient.

Thus it can be seen that the conventional switch box still has many shortcomings, it is not a good design and needs to be improved.

### SUMMARY OF THE INVENTION

One object of the present invention is to provide a signal switching (distributing) box structure, capable of reducing use space greatly and increasing use life.

Another object of the present invention is to provide a signal switching (distributing) box structure, capable of avoiding electromagnetic interference.

Still another object of the present invention is to provide a signal switching (distributing) box structure, in which the structure is simple and the manufacturing is easy.

For attaining to the objects mentioned above, a signal switching (distributing) box structure according to the present invention comprises a upper housing and lower housing, the internal portion thereof is allowed to form a receiving space so as to receive other electronic elements of the switching box through the combination of the upper housing and the lower housing. At least one side of the lower housing is provided with one or more than one receiving hole for receiving a head of each adaptor and the rear end of the receiving hole is connected with a fixing sheet inside the lower housing. Positioning holes corresponding to the receiving holes are disposed on the fixing sheet to allow the heads of the adaptors to be locked through the disposition of the positioning holes, two side of the fixing sheet are respectively disposed with at least one fixing rod; the fixing sheet is allowed to fix on the lower housing through the disposition of the fixing rods and locking holes. The heads of the adaptors are completely received in the receiving holes to enable them not to be exposed outside the outer rim of the housing when the head of the adaptor is locked on the fixing sheet. In the meantime, the heads of the adaptors are allowed to receive in the upper and the lower housings when they are combined with each other. This can avoid not only a collision when the box is moved, but also electromagnetic wave interference effectively when the box is used. Besides, the disposition of the receiving holes of the lower housing can be disposed not only on the front end thereof, but also other ends thereof. This can broad the use range greatly.

### BRIEF DESCRIPTION OF THE DRAWINGS

The present invention can be more fully understood by reference to the following description and accompanying drawings, in which:

FIG. 1 is an exploded view, showing a signal switching (distributing) box structure of a preferred embodiment according to the present invention;

FIG. 2 is an exploded view, showing an upper housing and a lower housing of a preferred embodiment according to the present invention;

FIG. 3 is a perspective view, showing a signal switching (distributing) box structure of a preferred embodiment according to the present invention;

FIG. 4 is an exploded view, showing a signal switching (distributing) box structure of a preferred embodiment according to the present invention put into practice; and

FIG. 5 is a perspective view, showing a signal switching (distributing) box structure of a preferred embodiment according to the present invention put into practice.

### DETAILED DESCRIPTION OF THE PREFERRED EMBODIMENTS

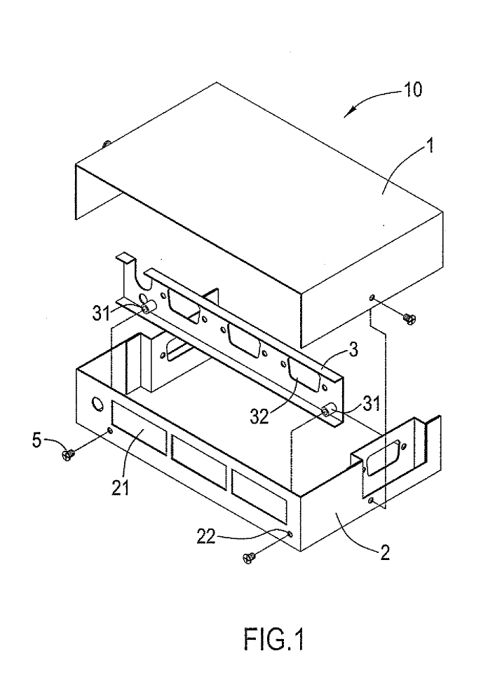

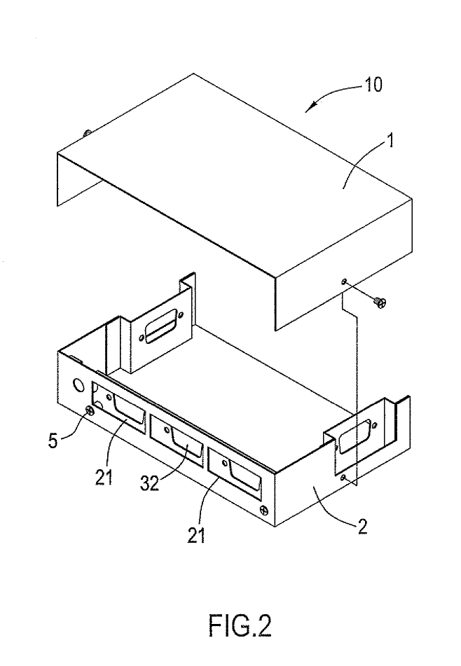

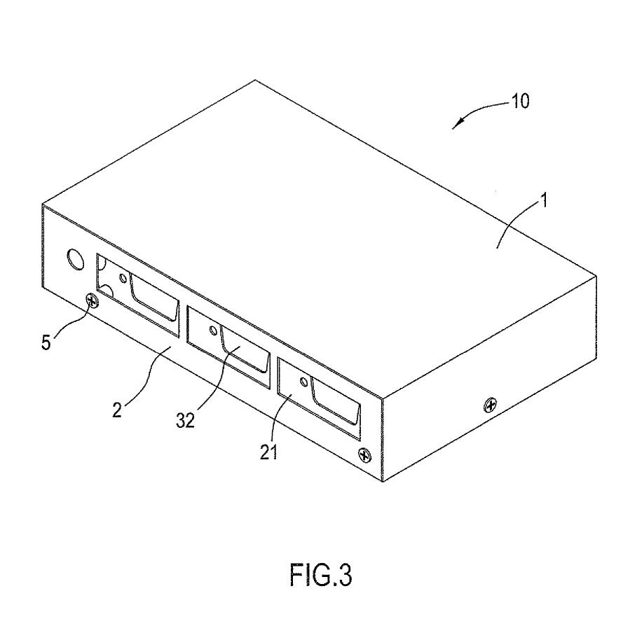

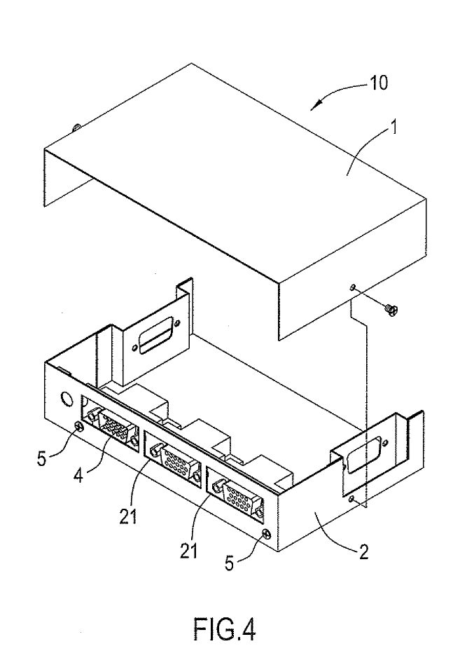

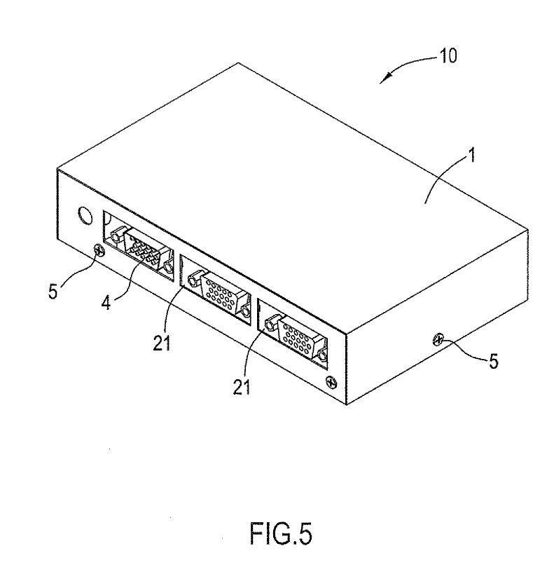

Please refer to FIGS. 1 to 5. The figures respectively are perspective, exploded and schematic views of a signal switching (distributing) box structure of a preferred embodiment according to the present invention. The signal switching box structure comprises an upper housing 1 and a lower housing 2, in which the upper housing 1 and the lower housing 2 are made from metal material. A receiving space is allowed to form inside after the upper housing 1 is combined with the lower housing 2 and then used to receive other electronic elements needed for the switching box 10. The front end of the lower housing 2 is provided with at least one receiving holes 21 used for receiving a head 4 of each adaptor. A fixing sheet 3 is connected with the lower housing 2 at the rear end of the receiving holes 21. Furthermore, locking holes 22 respectively corresponding to positioning rods 31 of the fixing sheet 3 are disposed on the front end of the lower housing 2. The fixing sheet 3 is U-shaped and positioning holes 32 respectively corresponding to the receiving holes are disposed on the fixing sheet 3 and the type of the positioning holes 32 can be can be changed by matching up with the type of the head 4. The heads can be locked through the disposition of the positioning holes 32. Two sides of the fixing sheet 3 are respectively disposed with at least one fixing rod 31. The fixing sheet 3 can be fixed to the lower housing 2 through the disposition of the fixing rods 31 and the locking of locking elements 5. The heads 4 can be completely received in the receiving holes 21 when the heads 4 are locked on the fixing sheet 3 such that they are not exposed out of the outer rim of the lower housing 2. The heads can be completely received inside after the upper housing 1 and the lower housing 2 are combined together. Therefore, the collision can be avoided when the box is moved, and the electromagnetic can be avoided effectively when the box is used. Besides, the receiving holes 21 of the lower housing 2 can be disposed on the front end of the lower housing 2, but also on other ends of the box 10 so as to broad the use range greatly.

Comparing to the conventional signal switching box structure, the signal switching (distributing) box structure of the preferred embodiment according to the present invention has the following merits:
1. the head of the adaptor of the present invention is received in the main body of the box; it enables the head not to be rusted and rather not to have a collision so as to enhance the use life broadly.
2. the head of the adaptor of the present invention is received in the main body of the box and the main body is made from metal material; it can avoid the electromagnetic wave interference greatly.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A signal switching (distributing) case structure, comprising a upper housing and a lower housing, enabling an internal portion thereof to form a receiving space, one side of said lower housing being provided with one or more than one receiving hole, a fixing sheet being installed along therewith on said lower housing at the rear ends thereof, and a positioning hole corresponding to each receiving hole is disposed on said fixing sheet to allow said positioning hole to lock ahead of an adaptor to cause said head of said adaptor to be received in said receiving hole of said lower housing.

2. The structure according to claim 1, wherein said upper housing and said lower housing are made from metal material.

3. The structure according to claim 1, wherein the front end of said lower housing is provided with locking holes corresponding to said fixing sheet so as to allow said lower housing to be fixed with said fixing through locking elements.

4. The structure according to claim 1, wherein said fixing sheet is U-shaped.

5. The structure according to claim 1, wherein a type of said positioning hole is changed by matching up with a type of said head.

6. The structure according to claim 3, wherein two sides of said fixing sheet are respectively disposed with at least one fixing rod, said fixing sheet is allowed to fix to said lower housing through the disposition of said fixing rods and the locking of said locking elements.
